(19) United States
(12) Patent Application Publication
(10) Pub. No.: US 2023/0333459 A1
(43) Pub. Date: Oct. 19, 2023

(54) REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventor: Yohei IKEBE, Tokyo (JP)

(73) Assignee: HOYA CORPORATION, Tokyo (JP)

(21) Appl. No.: 18/025,461

(22) PCT Filed: Sep. 24, 2021
(86) PCT No.: PCT/JP2021/035032

§ 371 Date: Mar. 9, 2023

(30) Foreign Application Priority Data
Sep. 28, 2020 (JP) 2020-162197

(51) Int. Cl. G03F 1/24; G03F 1/54; G03F 1/48

(52) U.S. Cl. CPC G03F 1/24; G03F 1/54; G03F 1/48

(57) ABSTRACT

Provided is a reflective mask blank for manufacturing a reflective mask capable of forming a transfer pattern of diversified fine pattern shapes formed on a transferred substrate and having a transfer pattern capable of performing EUV exposure with a high throughput

A reflective mask blank comprises a multilayer reflective film and an absorber film in this order on a substrate. When normalization is performed with a value of an evaluation function of a film having a refractive index of 0.95 and an extinction coefficient of 0.03 as 1, the absorber film comprises a material having such a refractive index and an extinction coefficient that a value of the normalized evaluation function of the absorber film is 1.015 or more, and the evaluation function is a product of a normalized image log slope (NILS) and a threshold of light intensity for exposure of a predetermined resist to light.

### CROSS-REFERENCE TO RELATED APPLICATIONS

This application is the National Stage of International Application No. PCT/JP2021/035032, filed Sep. 24, 2021, which claims priority to Japanese Patent Application No. 2020-162197, filed Sep. 28, 2020, and the contents of which is incorporated by reference.

### TECHNICAL FIELD

The present disclosure relates to a reflective mask blank that is an original plate for manufacturing an exposure mask used for manufacturing a semiconductor device or the like, a reflective mask, and a method for manufacturing a semiconductor device using the reflective mask.

### BACKGROUND ART

Types of light sources of exposure apparatuses in manufacturing semiconductor devices have been evolving while wavelengths thereof have been shortened gradually like a g-line having a wavelength of 436 nm, an i-line having a wavelength of 365 nm, a KrF laser having a wavelength of 248 nm, and an ArF laser having a wavelength of 193 nm. In order to achieve finer pattern transfer, extreme ultra violet (EUV) lithography using EUV having a wavelength around 13.5 nm has been developed. In EUV lithography, a reflective mask is used because there are few materials transparent to EUV light. The reflective mask includes a multilayer reflective film for reflecting exposure light on a low thermal expansion substrate. The reflective mask has, as a basic structure, a mask structure in which a desired transfer pattern is formed on a protective film for protecting the multilayer reflective film. In addition, from a configuration of the transfer pattern, there are a binary type reflective mask and a phase shift type reflective mask (halftone phase shift type reflective mask) as representative reflective masks. The transfer pattern of the binary type reflective mask includes a relatively thick absorber pattern that sufficiently absorbs EUV light. The transfer pattern of the phase shift type reflective mask includes a relatively thin absorber pattern that reduces EUV light by light absorption and generates reflected light having a phase substantially inverted (a phase inverted by approximately 180 degrees) with respect to reflected light from the multilayer reflective film. The phase shift type reflective mask (halftone phase shift type reflective mask) can obtain high transfer optical image contrast by a phase shift effect like a transmission type optical phase shift mask, and therefore a resolution can be improved. In addition, since the absorber pattern (phase shift pattern) of the phase shift type reflective mask has a thin film thickness, a fine and highly accurate phase shift pattern can be formed.

In EUV lithography, a projection optical system including a large number of reflecting mirrors is used due to a relationship of light transmittance. EUV light is made obliquely incident on the reflective mask, whereby the plurality of reflecting mirrors does not block projection light (exposure light). At present, an incident angle of 6° with respect to a vertical plane of a reflective mask substrate is the mainstream. Along with improvement of a numerical aperture (NA) of the projection optical system, studies are being conducted toward making the incident angle about 8° that is a more oblique incident angle.

In EUV lithography, since exposure light is obliquely incident, there is an inherent problem called a shadowing effect. The shadowing effect is a phenomenon in which exposure light is obliquely incident on an absorber pattern having a three-dimensional structure to form a shadow and the dimension and position of a transferred and formed pattern change. The three-dimensional structure of the absorber pattern serves as a wall and a shadow is formed on a shade side, resulting in changing the dimension and/or the position of the pattern to be transferred and formed. For example, there are differences in the dimension and position of a transfer pattern between a case where the orientation of the absorber pattern to be formed is parallel to a direction of obliquely incident light and a case where the orientation of the absorber pattern to be formed is perpendicular to the direction of the obliquely incident light, which decreases transfer accuracy.

Patent Documents 1 and 2 disclose techniques related to such a reflective mask for EUV lithography and a mask blank for manufacturing the same. In addition, Patent Document 1 describes providing a reflective mask having a small shadowing effect, capable of phase shift exposure, and having sufficient light shielding frame performance. Conventionally, the film thickness of the phase shift pattern is made relatively thin as compared with the case of the binary type reflective mask by using the phase shift type reflective mask as the reflective mask for EUV lithography, whereby a decrease in transfer accuracy due to the shadowing effect is suppressed.

Patent Document 3 describes a mask for EUV lithography. Specifically, the mask described in Patent Document 3 includes a substrate, a multilayer coating applied to the substrate, and a mask structure applied to the multilayer coating and containing an absorber material. Patent Document 3 describes that the mask structure has a maximum thickness of less than 100 nm.

Patent Document 4 describes a method for manufacturing an extreme ultraviolet (EUV) mask blank. Specifically, it is described that the method described in Patent Document 4 includes forming a substrate, forming a stack of a plurality of reflection layers on the substrate, forming a capping layer on the stack of the plurality of reflection layers, and forming an absorption layer on the capping layer. In addition, Patent Document 4 describes that the absorption layer contains an alloy of at least two different absorption materials.

### PRIOR ART DOCUMENTS

### Patent Documents

Patent Document 1: JP 2009-212220 A
Patent Document 2: JP 2004-39884 A
Patent Document 3: JP 2013-532381 A
Patent Document 4: JP 2019-527382 A

### DISCLOSURE OF INVENTION

### Technical Problem

In EUV lithography, a resist transfer pattern is transferred onto a resist layer formed on a transferred substrate (semiconductor substrate) using a transfer pattern formed on a reflective mask. A predetermined fine circuit is formed on a semiconductor device using the resist transfer pattern.

In order to enhance electrical characteristic performance of the semiconductor device, to improve the degree of integration, and to reduce a chip size, it is required to make the transfer pattern finer, that is, to make the dimension of the transfer pattern smaller and to enhance positional accuracy of the transfer pattern. Therefore, EUV lithography is required to have transfer performance for transferring a transfer pattern with higher accuracy and a finer dimension than before. It is presently required to form an ultrafine and highly accurate transfer pattern applicable to a half pitch 16 nm (hp 16 nm) generation. In response to such a requirement, a transfer pattern formed on a reflective mask is also required to be further finer. In addition, in order to reduce the shadowing effect at the time of EUV exposure, it is required to further reduce the thickness of a thin film constituting the transfer pattern of the reflective mask. In particular, the film thickness of an absorber film (phase shift film) of the reflective mask is required to be 50 nm or less.

Furthermore, as the transfer pattern is finer, the pattern shape of the transfer pattern is also diversified. Therefore, an absorber film for forming a transfer pattern applicable to diversified pattern shapes is required for the reflective mask.

In addition, in order to manufacture a semiconductor device at low cost, it is required to be able to perform EUV exposure of EUV lithography with a high throughput.

As disclosed in Patent Documents 1 and 2, Ta has been conventionally used as a material for forming an absorber film (phase shift film) of a reflective mask blank. However, since Ta has a refractive index (n) of about 0.943 in EUV light (for example, wavelength: 13.5 nm), a limit of thinning the absorber film (phase shift film) formed only of Ta is 60 nm even if a phase shift effect of Ta is utilized. In order to further thinning, a metal material having a high extinction coefficient (k) (having a high absorption effect) can be used, for example, as an absorber film of a binary type reflective mask blank. For example, Patent Documents 3 and 4 describe platinum (Pt) and iridium (Ir) as metal materials having a large extinction coefficient (k) at a wavelength of 13.5 nm.

However, it has been found that, only with the high extinction coefficient (k) of the absorber film, application to diversification of the pattern shape of the transfer pattern formed on the transferred substrate is difficult even if a requirement for thinning the absorber film of the reflective mask can be satisfied. Furthermore, it is difficult to satisfy a requirement for performing EUV exposure with a high throughput.

### Solution to Problem

In view of the above points, an aspect of the present disclosure is to provide a reflective mask blank for manufacturing a reflective mask capable of forming a transfer pattern of diversified fine pattern shapes formed on a transferred substrate and having a transfer pattern capable of performing EUV exposure with a high throughput.

Another aspect of the present disclosure is to provide a reflective mask capable of forming a transfer pattern of diversified fine pattern shapes formed on a transferred substrate and having a transfer pattern capable of performing EUV exposure with a high throughput. Still another aspect of the present disclosure is to provide a method for manufacturing a semiconductor device capable of forming diversified fine pattern shapes on a transferred substrate with a high throughput.

In order to solve the above problems, an embodiment of the present disclosure has the following configurations.

(Configuration 1)
Configuration 1 of the present embodiment is a reflective mask blank comprising a multilayer reflective film and an absorber film in this order on a substrate, in which
when normalization is performed with a value of an evaluation function of a film having a refractive index of 0.95 and an extinction coefficient of 0.03 for EUV light having a wavelength of 13.5 nm as 1, the absorber film comprises a material having such a refractive index and an extinction coefficient that a value of the normalized evaluation function of the absorber film is 1.015 or more, and
the evaluation function is a product of a normalized image log slope (NILS) and a threshold of light intensity for exposure of a predetermined resist to light.

(Configuration 2)
Configuration 2 of the present embodiment is the reflective mask blank according to configuration 1, in which the reflective mask blank is used to manufacture a reflective mask comprising a transfer pattern comprising a line and space of a LOGIC hp 16 nm generation or later.

(Configuration 3)
Configuration 3 of the present embodiment is the reflective mask blank according to configuration 1 or 2, in which the refractive index of the material of the absorber film for EUV light having a wavelength of 13.5 nm is within a range of 0.86 to 0.95, and the extinction coefficient of the material of the absorber film for EUV light having a wavelength of 13.5 nm is within a range of 0.015 to 0.065.

(Configuration 4)
Configuration 4 of the present embodiment is the reflective mask blank according to any one of configurations 1 to 3, in which the material of the absorber film comprises at least one selected from iridium (Ir) and ruthenium (Ru).

(Configuration 5)
Configuration 5 of the present embodiment is the reflective mask blank according to any one of configurations 1 to 3, in which the material of the absorber film comprises iridium (Ir) and at least one selected from the group consisting of boron (B), silicon (Si), ruthenium (Ru), tantalum (Ta), and oxygen (O).

(Configuration 6)
Configuration 6 of the present embodiment is the reflective mask blank according to any one of configurations 1 to 5, in which the material of the absorber film comprises platinum (Pt).

(Configuration 7)
Configuration 7 of the present embodiment is the reflective mask blank according to any one of configurations 1 to 5, in which the material of the absorber film comprises gold (Au).

(Configuration 8)
Configuration 8 of the present embodiment is the reflective mask blank according to any one of configurations 1 to 7, comprising a protective film between the multilayer reflective film and the absorber film, in which the protective film is formed of a material comprising ruthenium (Ru) or silicon (Si).

(Configuration 9)
Configuration 9 of the present embodiment is a reflective mask comprising an absorber pattern in which the absorber film of the reflective mask blank according to any one of configurations 1 to 8 is patterned.

(Configuration 10)
Configuration 10 of the present embodiment is a method for manufacturing a semiconductor device, the method comprising setting the reflective mask according to configuration 9 in an exposure apparatus comprising an exposure light source that emits EUV light and transferring a transfer pattern onto a resist layer formed on a transferred substrate.

### Advantageous Effects of Disclosure

According to the embodiment of the present disclosure, it is possible to provide a reflective mask blank for manufacturing a reflective mask capable of forming a transfer pattern of diversified fine pattern shapes formed on a transferred substrate and having a transfer pattern capable of performing EUV exposure with a high throughput.

In addition, according to the embodiment of the present disclosure, it is possible to provide a reflective mask capable of forming a transfer pattern of diversified fine pattern shapes formed on a transferred substrate and having a transfer pattern capable of performing EUV exposure with a high throughput. In addition, according to the embodiment of the present disclosure, it is possible to provide a method for manufacturing a semiconductor device capable of forming diversified fine pattern shapes on a transferred substrate with a high throughput.

### BRIEF DESCRIPTION OF DRAWINGS

FIG. 1 is a main part schematic cross-sectional view for describing a schematic configuration of a reflective mask blank of an embodiment of the present disclosure.

FIGS. 2A to 2D are process views illustrating a process for manufacturing a reflective mask from a reflective mask blank in main part schematic cross-sectional views.

FIG. 3 is a diagram illustrating values of a normalized evaluation function obtained by simulation in Example 1-1, and is a diagram illustrating a distribution of values of the normalized evaluation function with respect to a refractive index (n) and an extinction coefficient (k) of an absorber film when a reflective mask has a vertical line and space (L/S) pattern having a hp of 16 nm and a RuNb film is used as a protective film (Cap film).

FIG. 4 is a diagram illustrating values of a normalized evaluation function obtained by simulation in Example 1-2, and is a diagram illustrating a distribution of values of the normalized evaluation function with respect to a refractive index (n) and an extinction coefficient (k) of an absorber film when a reflective mask has a vertical L/S pattern having a hp of 16 nm and a RuRh film is used as a protective film.

FIG. 5 is a diagram illustrating values of a normalized evaluation function obtained by simulation in Example 1-1, and is a diagram illustrating a distribution of values of the normalized evaluation function with respect to a refractive index (n) and an extinction coefficient (k) of an absorber film when a reflective mask has a horizontal L/S pattern having a hp of 16 nm and a RuNb film is used as a protective film.

FIG. 6 is a diagram illustrating values of a normalized evaluation function obtained by simulation in Example 1-2, and is a diagram illustrating a distribution of values of the normalized evaluation function with respect to a refractive index (n) and an extinction coefficient (k) of an absorber film when a reflective mask has a horizontal L/S pattern having a hp of 16 nm and a RuRh film is used as a protective film.

FIG. 7 is a diagram illustrating values of a normalized evaluation function obtained by simulation in Example 1-1, and is a diagram illustrating a distribution of values of the normalized evaluation function with respect to a refractive index (n) and an extinction coefficient (k) of an absorber film when a reflective mask has a contact hole pattern having a diameter of 24 nm and a RuNb film is used as a protective film.

FIG. 8 is a diagram combining distributions of values of the normalized evaluation function of the vertical L/S patterns illustrated in FIGS. 3 and 4, and is a diagram illustrating a distribution obtained by binarizing the combined distribution into a case where values of the normalized evaluation function illustrated in FIGS. 3 and 4 are both 1.015 or more (white) and the other cases (black).

FIG. 9 is a diagram combining distributions of values of the normalized evaluation function of the horizontal L/S patterns illustrated in FIGS. 5 and 6, and is a diagram illustrating a distribution obtained by binarizing the combined distribution into a case where values of the normalized evaluation function illustrated in FIGS. 5 and 6 are both 1.015 or more (white) and the other cases (black).

FIG. 10 is a diagram illustrating a distribution obtained by binarizing the distribution of values of the normalized evaluation function of the contact hole pattern illustrated in FIG. 7 into a case where a value of the evaluation function is 1.015 or more (white) and a case where a value of the evaluation function is less than 1.015 (black).

FIG. 11 is a diagram combining the binarized distributions of values of the normalized evaluation function illustrated in FIGS. 8 to 10, and is a diagram illustrating a distribution of a case where values of the normalized evaluation function illustrated in FIGS. 8 to 10 are all 1.015 or more (white) and the other cases (black).

### DESCRIPTION OF EMBODIMENTS

Hereinafter, an embodiment of the present disclosure will be specifically described with reference to the drawings. Note that the following embodiment is one mode for embodying the present disclosure and does not limit the present disclosure within the scope thereof. Note that in the drawings, the same or corresponding portions are denoted by the same reference signs, and description thereof may be simplified or omitted.

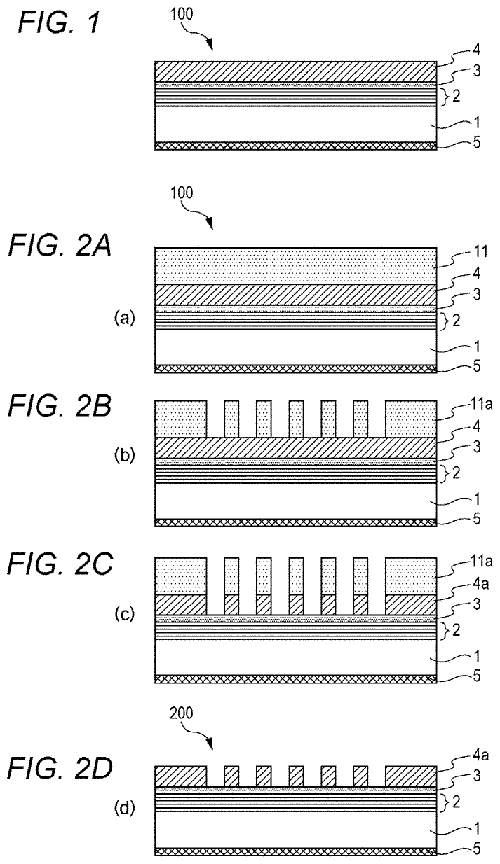

As illustrated in FIG. 1, a reflective mask blank 100 of the present embodiment is the reflective mask blank 100 including a multilayer reflective film 2 and an absorber film 4 in this order on a substrate 1. In addition, the reflective mask blank 100 of the present embodiment can include a protective film 3 between the multilayer reflective film 2 and the absorber film 4.

As illustrated in FIG. 2D, a reflective mask 200 of the present embodiment includes the multilayer reflective film 2 and an absorber pattern 4a in this order on the substrate 1. In addition, the reflective mask 200 of the present embodiment can include the protective film 3 between the multilayer reflective film 2 and the absorber pattern 4a and on a surface of the multilayer reflective film 2.

In the present specification, “line and space (L/S) pattern of a LOGIC hp 16 nm generation or later” means a line and space (L/S) pattern having a half pitch (hp) of 16 nm or less.

In the present specification, “normalized image log slope (NILS)” refers to one represented by the following formula 1. Note that, in formula 1, W (unit: nm) represents a pattern size, and I represents light intensity. “I=I_{threshold}” indicates that a differential is a predetermined differential value at a location corresponding to an edge of a pattern having a pattern size W (that is, a location where light intensity is a threshold described later). Note that, in the present specification, the normalized image log slope may be simply referred to as “NILS”.

$$( Formula 1 )$$

$$NILS = W \frac{d ln ( I )}{dx} {\vert}_{I = {I}_{threshold}} \qquad [ Mathematical formula 1 ]$$

The normalized image log slope (NILS) indicates the magnitude of an inclination when a horizontal axis indicates a position and a vertical axis indicates a logarithm of light intensity of exposure light. That is, the higher the NILS is, the higher the contrast is. In EUV lithography, a predetermined transfer pattern is transferred onto a resist layer on a transferred substrate. A resist of the resist layer is exposed to light according to a dose amount of exposure light (obtained by multiplying light intensity by time). Therefore, when the exposed resist is developed, the inclination of the shape of a pattern edge portion of the transfer pattern increases as the contrast (NILS) increases. When the inclination of the shape of the pattern edge portion is large (steep), dependence of the position of the pattern edge on the dose amount of exposure light is small. Therefore, even when there is a variation in the dose amount, a change in the shape of the transfer pattern is small. From the above, the normalized image log slope (NILS) is preferably high in order to obtain a fine and highly accurate transfer pattern. In addition, it can be said that as the normalized image log slope (NILS) is higher, it is possible to more easily form a transfer pattern of diversified fine pattern shapes formed on the transferred substrate.

The normalized image log slope (NILS) varies depending on the material and the shape of the absorber pattern 4a of the reflective mask 200. This is because, in an exposure step, the light intensity of reflected exposure light reflected by the reflective mask 200 and projected onto the transferred substrate and a distribution thereof are affected by the material and the shape of the absorber pattern 4a of the reflective mask 200. More specifically, the normalized image log slope (NILS) depends on the refractive index (n) and the extinction coefficient (k) of the material of the absorber pattern 4a, the film thickness of the absorber pattern 4a, and the like. Therefore, it can be said that the reflective mask 200 having the absorber pattern 4a of a predetermined material has a predetermined normalized image log slope (NILS). In addition, since the material and the film thickness of the absorber pattern 4a affect the normalized image log slope (NILS) in the reflective mask 200, the normalized image log slope (NILS) can be conceived according to the material and the film thickness of the absorber film 4. In addition, when the film thickness is optimized, the normalized image log slope (NILS) can be conceived according to the material of the absorber film 4. Therefore, in the present specification, the normalized image log slope (NILS) in the exposure step using the predetermined reflective mask 200 may be referred to as a normalized image log slope (NILS) of the reflective mask 200 (having the absorber pattern 4a of a predetermined material) or a normalized image log slope (NILS) of the reflective mask blank 100 (having the absorber film 4 of a predetermined material).

In the present specification, “threshold” refers to light intensity with which a resist is exposed to light at a predetermined hp at the time of EUV exposure for forming a resist transfer pattern of a line and space pattern (also simply described as “L/S” in the present specification) of a predetermined half pitch (also simply described as “hp” in the present specification). For example, in a graph (aerial image) having a shape in which a vertical axis indicates light intensity and a horizontal axis indicates a hp of L/S, “threshold” refers to light intensity at which a resist is exposed to light at a predetermined hp. Specifically, for example, in a case where a negative photosensitive material is used as the resist, the threshold means light intensity at which the negative photosensitive material is completely insoluble when development is performed after exposure to light at a predetermined light intensity. The higher the threshold is, the smaller the dose amount of exposure light at the time of EUV exposure is, and therefore the throughput of the EUV exposure step increases. Therefore, in order to increase the throughput of the EUV exposure step, the threshold is preferably high.

The threshold varies depending on the photosensitivity of the resist layer on the transferred substrate and the shape of the transfer pattern (specifically, half pitch (hp) of L/S). In the exposure step, the shape of the transfer pattern (resist transfer pattern) transferred onto the transferred substrate depends on the light intensity of reflected exposure light reflected by the reflective mask 200 and projected onto the transferred substrate and a distribution thereof. The light intensity of the reflected exposure light and a distribution thereof are affected by the material and the shape of the absorber pattern 4a of the reflective mask 200. More specifically, the threshold varies depending on the refractive index (n) and the extinction coefficient (k) of the material of the absorber pattern 4a, the film thickness of the absorber pattern 4a, the shape of the absorber pattern 4a such as a hp of L/S, and the like. Therefore, it can be said that the reflective mask 200 has a predetermined threshold. In addition, since the material and the film thickness of the absorber pattern 4a affect the threshold in the reflective mask 200 in a case of the same hp of L/S, the threshold can be conceived according to the material and the film thickness of the absorber film 4. In addition, when the film thickness is optimized, the threshold can be conceived according to the material of the absorber film 4. Therefore, in the present specification, the threshold in the exposure step using the predetermined reflective mask 200 may be referred to as a threshold of the reflective mask 200 (having the absorber pattern 4a of a predetermined material) or a threshold of the reflective mask blank 100 (having the absorber film 4 of a predetermined material).

In the present specification, “evaluation function” is a product of a normalized image log slope (NILS) and a threshold of light intensity for exposure of a predetermined resist to light. It can be said that as a value of the evaluation function of the reflective mask 200 having the absorber pattern 4a of a predetermined material is larger, a transfer pattern (resist transfer pattern) having diversified fine pattern shapes formed on the transferred substrate can be formed more easily, and EUV exposure can be performed with a higher throughput.

In the present specification, “normalized evaluation function” means a ratio of a value of the evaluation function obtained by normalizing a value of the evaluation function of a film to be compared with a value of the evaluation function of the reflective mask 200 using a pattern (reference film pattern) of a film (referred to as “reference film” in the present specification) having a refractive index (n) of 0.95 and an extinction coefficient (k) of 0.03 for EUV light having a wavelength of 13.5 nm as the absorber pattern 4a as 1.

Currently, a film containing Ta, for example, a TaBN film, a TaN film, or the like is often used as the absorber film 4 of the reflective mask 200. The refractive index (n) of each of the TaBN film and the TaN film is about 0.95, and the extinction coefficient (k) thereof is about 0.03. Therefore, as a reference film for calculating a value of the normalized evaluation function, a film having a refractive index (n) of 0.95 and an extinction coefficient (k) of 0.03 for EUV light having a wavelength of 13.5 nm is selected. The value of the normalized evaluation function is a ratio of a value of the evaluation function of the reflective mask 200 having the absorber pattern 4a to be compared to a value of the evaluation function of the reflective mask 200 having the pattern of the reference film (reference film pattern). Note that, as described above, originally, the value of the evaluation function is a value obtained as a product of a normalized image log slope (NILS) and a threshold of light intensity when a transfer pattern is transferred onto the resist layer on the transferred substrate using the predetermined reflective mask 200. Meanwhile, when the transfer patterns have the same pattern shape (that is, when the transfer patterns of the reflective mask 200 have the same pattern shape), the normalized image log slope (NILS) and the threshold can be conceived as a threshold of the material of the absorber film 4 constituting the transfer pattern of the reflective mask 200. Therefore, the value of the evaluation function can also be conceived for the material of the absorber film 4. Therefore, in the present specification, the value of the evaluation function may be described as a value of the evaluation function (or normalized evaluation function) of the predetermined absorber film 4 or a value of the evaluation function of the reference film. Similarly, the value of the evaluation function may be referred to as a value of the evaluation function (or normalized evaluation function) of the reflective mask 200 (having the absorber pattern 4a of a predetermined material) or a value of the evaluation function (or normalized evaluation function) of the reflective mask blank 100 (having the absorber film 4 of a predetermined material).

As described above, in the present specification, the evaluation function of the reflective mask 200 using the pattern of the reference film (reference film pattern) as the absorber pattern 4a may be simply referred to as an evaluation function of the reference film.

It can be said that as a value of the normalized evaluation function of the reflective mask 200 having the absorber pattern 4a of a predetermined material is larger, a transfer pattern having diversified fine pattern shapes formed on the transferred substrate can be formed more easily, and EUV exposure can be performed with a higher throughput as compared with the reflective mask 200 having the absorber pattern 4a of the reference film.

The present inventors have found an optimum refractive index (n) and an optimum extinction coefficient (k) of the absorber film 4 applicable to diversification of a pattern shape by focusing on a relationship among the normalized image log slope (NILS), the threshold, and the film thickness, and have completed the present disclosure. Specifically, the present inventors have found that, by forming the absorber film 4 using a material having a predetermined refractive index (n) and a predetermined extinction coefficient (k) in order to select the absorber film 4 in which a value of the above-described normalized evaluation function is within a predetermined range, it is possible to manufacture the reflective mask 200 capable of forming a transfer pattern of diversified fine pattern shapes formed on a transferred substrate and having a transfer pattern capable of performing EUV exposure with a high throughput, and have completed the present disclosure.

Next, the reflective mask blank 100 of the present embodiment will be described.

The present embodiment is the reflective mask blank 100 including the multilayer reflective film 2 and the absorber film 4 in this order on the substrate 1.

The absorber film 4 of the reflective mask blank 100 of the present embodiment contains a material having such a refractive index and an extinction coefficient that a value of a normalized evaluation function of the absorber film 4 is 1.015 or more. Note that “normalized evaluation function of the absorber film 4” means a normalized evaluation function in the exposure step of the reflective mask 200 when the reflective mask blank 100 is manufactured using the absorber film 4 and the reflective mask 200 is further manufactured. In a case where the reflective mask 200 serving as a reference for normalization and the reflective mask 200 serving as a target for normalization are used in the exposure step under the same conditions, when a difference between these reflective masks 200 is only the absorber film 4 (material and film thickness), even if “normalized evaluation function of the absorber film 4” is expressed, the absorber film 4 can be specified without causing misunderstanding.

As described above, the evaluation function is a product of a normalized image log slope (NILS) and a threshold of light intensity for exposure of a predetermined resist to light. In addition, a value of the normalized evaluation function is a value of an evaluation function normalized with a value of the evaluation function of the reference film. Note that an upper limit of the value of the normalized evaluation function can be conceived according to a requirement for making the transfer pattern finer. In order to be able to realistically select the material of the absorber film 4, an upper limit of the value of the normalized evaluation function is preferably 2.0 or less, and more preferably 1.7 or less.

The value of the normalized evaluation function is preferably 1.015 or more in any case where the transfer pattern is a vertical line and space (L/S) pattern, a horizontal L/S pattern, or a contact hole pattern. In this case, it is considered that exposure performance exceeds exposure performance in a case of using the Ta-based absorber film 4 which is the current mainstream.

Note that the vertical L/S pattern means an L/S pattern in which incident light is incident on the reflective mask 200 such that a normal line of a plane including incident light and reflected light with respect to the reflective mask 200 is perpendicular to a direction of a line of the L/S pattern. The horizontal L/S pattern means an L/S pattern in which incident light is incident on the reflective mask 200 such that a normal line of a plane including incident light and reflected light with respect to the reflective mask 200 is parallel to a direction of a line of the L/S pattern.

The reflective mask blank 100 of the present embodiment is preferably used to manufacture the reflective mask 200 having a transfer pattern including a line and space of a LOGIC hp 16 nm. This is because by using the reflective mask blank 100 of the present embodiment, it is possible to manufacture the reflective mask 200 capable of forming a transfer pattern of diversified fine pattern shapes formed on a transferred substrate and having a transfer pattern capable of performing EUV exposure with a high throughput, and have completed the present disclosure.

Next, a film constituting the reflective mask blank 100 of the present embodiment will be specifically described.

<Configuration of Reflective Mask Blank 100 and Method for Manufacturing the Same>

FIG. 1 is a main part schematic cross-sectional view for describing a schematic configuration of the reflective mask blank 100 of the embodiment of the present disclosure. As illustrated in FIG. 1, the reflective mask blank 100 includes the substrate 1, the multilayer reflective film 2 that is formed on a first main surface (front surface) side and reflects EUV light that is exposure light, the protective film 3 formed for protecting the multilayer reflective film 2, and the absorber film 4 that absorbs EUV light, and these are layered in this order. In addition, a conductive back film 5 for electrostatic chuck is formed on a side of a second main surface (back surface) of the substrate 1.

In addition, the above reflective mask blank 100 includes a configuration in which the conductive back film 5 is not formed. Furthermore, the above reflective mask blank 100 includes a configuration of a mask blank with a resist film in which a resist film 11 is formed on an etching mask film.

In the present specification, for example, the description “the multilayer reflective film 2 formed on the substrate 1” means that the multilayer reflective film 2 is formed in contact with a surface of the substrate 1 and also means that another film is formed between the substrate 1 and the multilayer reflective film 2. The same applies to other films. In addition, in the present specification, for example, the description “a film A is formed on a film B in contact with the film B” means that the film A and the film B are formed in direct contact with each other without another film interposed between the film A and the film B.

Hereinafter, each configuration of the reflective mask blank 100 will be specifically described.

«Substrate 1»

As the substrate 1, a material having a low thermal expansion coefficient within a range of 0±5 ppb/° C. is preferably used in order to prevent distortion of the absorber pattern 4a due to heat during exposure to EUV light. As a material having a low thermal expansion coefficient within this range, for example, SiO₂—TiO₂-based glass, multicomponent-based glass ceramics, or the like can be used.

The first main surface on a side of the substrate 1 on which a transfer pattern (constituted by a pattern obtained by patterning the absorber film 4 described later) is formed has been subjected to a surface treatment so as to have high flatness from a viewpoint of obtaining at least pattern transfer accuracy and position accuracy. In a case of EUV exposure, flatness in an area of 132 mm×132 mm of the main surface on the side of the substrate 1 on which the transfer pattern is formed is preferably 0.1 μm or less, more preferably 0.05 μm or less, and particularly preferably 0.03 μm or less. In addition, the second main surface on a side opposite to the side where the absorber film 4 is formed is a surface to be electrostatically chucked at the time of setting on an exposure apparatus, and in an area of 142 mm×142 mm of the second main surface, flatness is preferably 0.1 μm or less, more preferably 0.05 μm or less, and particularly preferably 0.03 μm or less.

In addition, high surface smoothness of the substrate 1 is also an extremely important item. Surface roughness of the first main surface of the substrate 1 on which the transfer pattern (absorber pattern 4a) is formed is preferably 0.1 nm or less in terms of root mean square roughness (RMS). Note that the surface smoothness can be measured with an atomic force microscope.

Furthermore, the substrate 1 preferably has high rigidity in order to prevent deformation due to film stress of a film (such as the multilayer reflective film 2) formed on the substrate 1. In particular, the substrate 10 preferably has a high Young's modulus of 65 GPa or more.

«Multilayer Reflective Film 2»

The multilayer reflective film 2 imparts a function of reflecting EUV light in the reflective mask 200, and has a configuration of a multilayer film in which layers containing elements having different refractive indexes as main components are periodically layered.

Generally, as the multilayer reflective film 2, a multilayer film is used in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. The multilayer film may be formed by counting, as one period, a stack of a high refractive index layer and a low refractive index layer in which the high refractive index layer and the low refractive index layer are layered in this order from the substrate 1 and building up the stack for a plurality of periods. In addition, the multilayer film may be formed by counting, as one period, a stack of a low refractive index layer and a high refractive index layer in which the low refractive index layer and the high refractive index layer are layered in this order from the substrate 1 and building up the stack for a plurality of periods. Note that a layer of the outermost surface of the multilayer reflective film 2, that is, a surface layer of the multilayer reflective film 2 on a side opposite to the substrate 1 is preferably a high refractive index layer. In the multilayer film described above, when a stack of a high refractive index layer and a low refractive index layer in which the high refractive index layer and the low refractive index layer are layered in this order from the substrate 1 is counted as one period and the stacks are built up for a plurality of periods, the uppermost layer is the low refractive index layer. In this case, if the low refractive index layer constitutes the outermost surface of the multilayer reflective film 2, the low refractive index layer is easily oxidized and the reflectance of the reflective mask 200 is reduced. Therefore, it is preferable to further form a high refractive index layer on the low refractive index layer which is the uppermost layer to form the multilayer reflective film 2. Meanwhile, in the multilayer film described above, when a stack of a low refractive index layer and a high refractive index layer in which the low refractive index layer and the high refractive index layer are layered in this order from the substrate 1 is counted as one period and the stack is built up for a plurality of periods, the uppermost layer is a high refractive index layer, which is good as it is.

In the present embodiment, a layer containing silicon (Si) is adopted as the high refractive index layer. As a material containing Si, a Si compound containing boron (B), carbon (C), nitrogen (N), and oxygen (O) in Si may be used in addition to a Si simple substance. By using the layer containing Si as the high refractive index layer, the reflective mask 200 for EUV lithography having an excellent EUV light reflectance can be obtained. In addition, in the present embodiment, a glass substrate is preferably used as the substrate 1. Si also has excellent adhesion to the glass substrate. In addition, as the low refractive index layer, a metal simple substance selected from the group consisting of molybdenum (Mo), ruthenium (Ru), rhodium (Rh), and platinum (Pt), or an alloy thereof is used. For example, as the multilayer reflective film 2 with respect to EUV light having a wavelength of 13 nm to 14 nm, a Mo/Si periodic layered film in which a Mo film and a Si film are alternately layered for about 40 to 60 periods is preferably used. Note that a high refractive index layer which is the uppermost layer of the multilayer reflective film 2 may be formed of silicon (Si), and a silicon oxide layer containing silicon and oxygen may be formed between the uppermost layer (Si) and the Ru-based protective film 3. This makes it possible to improve mask cleaning resistance.

The reflectance of such a multilayer reflective film 2 alone is usually 65% or more, and an upper limit thereof is usually 73%. Note that the thickness and period of each constituent layer of the multilayer reflective film 2 only need to be appropriately selected according to an exposure wavelength and are selected so as to satisfy the Bragg reflection law. In the multilayer reflective film 2, there are a plurality of high refractive index layers and a plurality of low refractive index layers. The film thicknesses of the high refractive index layers do not have to be the same as each other, and the film thicknesses of the low refractive index layers do not have to be the same as each other. In addition, the film thickness of the Si layer on the outermost surface of the multilayer reflective film 2 can be adjusted within a range that does not lower the reflectance. The film thickness of the Si (high refractive index layer) of the outermost surface can be 3 nm to 10 nm.

A method for forming the multilayer reflective film 2 is publicly known in this technical field. For example, the multilayer reflective film 2 can be formed by forming each layer in the multilayer reflective film 2 by an ion beam sputtering method. In the case of the Mo/Si periodic multilayer film described above, first, a Si film having a thickness of about 4 nm is formed on the substrate 1 using a Si target by, for example, an ion beam sputtering method. Thereafter, a Mo film having a thickness of about 3 nm is formed using a Mo target. This stack of a Si film and a Mo film is counted as one period and the stack is build up for 40 to 60 periods to form the multilayer reflective film 2 (the layer of the outermost surface is a Si layer). In addition, when the multilayer reflective film 2 is formed, the multilayer reflective film 2 is preferably formed by supplying krypton (Kr) ion particles from an ion source and performing ion beam sputtering. Note that the multilayer reflective film 2 preferably includes about 40 periods from a viewpoint of improvement in reflectance due to an increase in the number of layered periods, reduction in throughput due to an increase in the number of steps, and the like. Note that the number of layered periods of the multilayer reflective film 2 is not limited to 40, and may be, for example, 60. In a case of 60 periods, the number of steps is larger than the number of steps in a case of 40 periods, but reflectance for EUV light can be increased.

«Protective Film 3»

The reflective mask blank 100 of the present embodiment preferably includes the protective film 3 between the multilayer reflective film 2 and the absorber film 4. The protective film 3 is formed on the multilayer reflective film 2, and it is thereby possible to suppress damage to a surface of the multilayer reflective film 2 when the reflective mask 200 (EUV mask) is manufactured using the reflective mask blank 100. Therefore, by forming the protective film 3, a reflectance characteristic for EUV light is improved.

The protective film 3 is formed on the multilayer reflective film 2 in order to protect the multilayer reflective film 2 from dry etching and cleaning in a process for manufacturing the reflective mask 200 described later. In addition, the protective film 3 also protects the multilayer reflective film 2 when a black defect of the absorber pattern 4a is repaired using an electron beam (EB). The protective film 3 is formed of a material having resistance to an etchant, a cleaning liquid, and the like. Here, FIG. 1 illustrates a case where the protective film 3 has one layer, but the protective film 3 can have a stack of three or more layers. For example, the protective film 3 may be one in which a lowermost layer and an uppermost layer are layers formed of the substance containing Ru, and a metal or an alloy other than Ru is interposed between the lowermost layer and the uppermost layer. The protective film 3 can be formed of, for example, a material containing ruthenium as a main component. That is, the material of the protective film 3 may be a Ru metal simple substance or a Ru alloy containing Ru and at least one kind of metal selected from the group consisting of titanium (Ti), niobium (Nb), Rh (rhodium), molybdenum (Mo), zirconium (Zr), yttrium (Y), boron (B), lanthanum (La), cobalt (Co), rhenium (Re), and the like, and may contain nitrogen. Such a protective film 3 is particularly effective in a case where the absorber film 4 is patterned by dry etching of a chlorine-based gas (Cl-based gas). The protective film 3 is preferably formed of a material having an etching selective ratio of 1.5 or more, preferably 3 or more, the etching selective ratio being an etching selective ratio of the absorber film 4 to the protective film 3 (etching rate of absorber film 4/etching rate of protective film 3) in dry etching using a chlorine-based gas.

When a Ru alloy is used as the material of the protective film 3, the Ru content of the Ru alloy is 50 atomic % or more and less than 100 atomic %, preferably 80 atomic % or more and less than 100 atomic %, and more preferably 95 atomic % or more and less than 100 atomic %. In particular, when the Ru content ratio of the Ru alloy is 95 atomic % or more and less than 100 atomic %, the reflectance for EUV light can be ensured sufficiently while diffusion of an element (silicon) constituting the multilayer reflective film 2 to the protective film 3 is suppressed. Furthermore, this protective film 3 can have mask cleaning resistance, an etching stopper function when the absorber film 4 (specifically, buffer layer 42) is etched, and a protective film 3 function for preventing a temporal change in the multilayer reflective film 2.

The material of the protective film 3 may be a material containing silicon (Si). The material containing silicon (Si) includes, for example, at least one material selected from the group consisting of silicon (Si), a silicon oxide (SiₓO_{y} (x and y are integers of 1 or more) such as SiO, SiO₂, or Si₃O₂), a silicon nitride (SiₓN_{y} (x and y are integers of 1 or more) such as SiN or Si₃N₄), and a silicon oxynitride (SiₓO_{y}N_{z} (x, y, and z are integers of 1 or more) such as SiON). Such a protective film 3 is particularly effective when the absorber film 4 is patterned by dry etching of a chlorine-based gas (Cl-based gas) containing an oxygen gas. The protective film 3 is preferably formed of a material having an etching selective ratio of 1.5 or more, preferably 3 or more, the etching selective ratio being an etching selective ratio of the absorber film 4 to the protective film 3 (etching rate of absorber film 4/etching rate of protective film 3) in dry etching using a chlorine-based gas containing an oxygen gas.

In the reflective mask blank 100 of the present embodiment, the protective film 3 is preferably formed of a material containing ruthenium (Ru) or silicon (Si). The protective film 3 is formed of a material containing ruthenium (Ru) (for example, a Ru simple substance or a Ru alloy), and damage to a surface of the multilayer reflective film 2 can be thereby effectively suppressed. In addition, the protective film 3 is formed of a material containing silicon (Si), and the degree of freedom in selecting a material of the absorber film 4 can be thereby increased.

In EUV lithography, since there are few substances that are transparent to exposure light, it is not technically easy to achieve an EUV pellicle that prevents foreign matters from being attached to a mask pattern surface. For this reason, pellicle-less operation without using a pellicle has been the mainstream. In addition, in EUV lithography, exposure contamination such as carbon film deposition on a mask or an oxide film growth due to EUV exposure occurs. Therefore, it is necessary to remove foreign matters and contamination on the EUV reflective mask 200 by frequent cleaning at a stage where the EUV reflective mask 200 is used for manufacturing a semiconductor device. For this reason, the EUV reflective mask 200 is required to have extraordinary mask cleaning resistance as compared with a transmission type mask for optical lithography. When the Ru-based protective film 3 containing Ti is used, cleaning resistance to a cleaning liquid such as sulfuric acid, sulfuric acid peroxide (SPM), ammonia, ammonia peroxide (APM), OH radical cleaning water, or ozone water having a concentration of 10 ppm or less is particularly high, and requirement for mask cleaning resistance can be satisfied.

The film thickness of such a protective film 3 formed of Ru, an alloy thereof, silicon (Si), or the like is not particularly limited as long as a function as the protective film 3 can be exhibited. The film thickness of the protective film 3 is preferably 1.0 nm to 8.0 nm and more preferably 1.5 nm to 6.0 nm from a viewpoint of the reflectance for EUV light.

As a method for forming the protective film 3, it is possible to adopt a film forming method similar to a publicly known one without any particular limitation. Specific examples thereof include a sputtering method and an ion beam sputtering method.

«Absorber Film 4»

The reflective mask blank 100 of the present embodiment includes the multilayer reflective film 2 and the absorber film 4 in this order on the substrate 1. More specifically, in the reflective mask blank 100 of the present embodiment, the absorber film 4 that absorbs EUV light is formed on the multilayer reflective film 2 or the protective film 3. The absorber film 4 has a function of absorbing EUV light.

The absorber film 4 of the reflective mask blank 100 of the present embodiment contains a predetermined material having such a refractive index and an extinction coefficient that a value of a normalized evaluation function of the absorber film 4 is 1.015 or more, preferably 1.03 or more, and more preferably 1.05 or more when normalization is performed with a value of an evaluation function of a film having a refractive index of 0.95 and an extinction coefficient of 0.03 as 1. The absorber film 4 of the reflective mask blank 100 of the present embodiment can be formed only of a predetermined material having a predetermined value of the evaluation function. It can be said that, by inclusion of a predetermined material in the absorber film 4 of the reflective mask blank 100 of the present embodiment, it is possible to form a transfer pattern of diversified fine pattern shapes formed on a transferred substrate, and it is possible to obtain the reflective mask blank 100 for manufacturing the reflective mask 200 capable of forming a transfer pattern of diversified fine pattern shapes formed on a transferred substrate and having a transfer pattern capable of performing EUV exposure with a high throughput as compared with the conventional absorber film 4 containing a TaBN film, a TaN film, or the like.

As described above, the evaluation function is a product of a normalized image log slope (NILS) and a threshold of light intensity for exposure of a predetermined resist to light. Note that an upper limit of the value of the normalized evaluation function can be conceived according to a requirement for making the transfer pattern finer. In order to be able to realistically select the material of the absorber film 4, an upper limit of the value of the normalized evaluation function is preferably 2.0 or less, and more preferably 1.7 or less.

In the reflective mask blank 100 of the present embodiment, the refractive index of the material of the absorber film 4 is preferably within a range of 0.86 to 0.95, and the extinction coefficient of the material of the absorber film 4 is preferably within a range of 0.015 to 0.065. When the refractive index and the extinction coefficient of the material of the absorber film 4 are within the predetermined ranges, a material having such a refractive index and an extinction coefficient that a value of the normalized evaluation function of the absorber film 4 is 1.015 or more can be relatively easily obtained.

Examples of a material of a simple substance belonging to an area where a value of the normalized evaluation function is 1.015 or more include Ag, Co, Pt, Au, Fe, Pd, Ir, W, Cr, Rh, Ru, and the like. In addition, an alloy containing one or more selected from the group consisting of Ag, Co, Pt, Au, Fe, Pd, Ir, W, Cr, Rh, and Ru such that a value of the normalized evaluation function is 1.015 or more, and a material containing a simple substance of Ag, Co, Pt, Au, Fe, Pd, Ir, W, Cr, Rh, or Ru or the above alloy and one or more elements selected from the group consisting of oxygen (O), nitrogen (N), carbon (C), boron (B), and hydrogen (H) can be exemplified. Therefore, when the absorber film 4 is formed using these materials, it can be said that it is possible to form a transfer pattern of diversified fine pattern shapes formed on a transferred substrate, and it is possible to obtain the reflective mask blank 100 for manufacturing the reflective mask 200 capable of forming a transfer pattern of diversified fine pattern shapes formed on a transferred substrate and having a transfer pattern capable of performing EUV exposure with a high throughput as compared with the conventional absorber film 4 containing a TaBN film, a TaN film, or the like.

Specific examples of the material having a value of the normalized evaluation function of 1.015 or more include Ir, Pt, and an IrTa alloy (for example, atomic ratio Ir:Ta=4:1).

In the reflective mask blank 100 of the present embodiment, the material of the absorber film 4 preferably contains at least one selected from iridium (Ir) and ruthenium (Ru).

Iridium (Ir) has a refractive index of 0.905 and an extinction coefficient of 0.044. Ruthenium (Ru) has a refractive index of 0.886 and an extinction coefficient of 0.017. Therefore, by inclusion of at least one selected from iridium (Ir) and ruthenium (Ru) in the material of the absorber film 4, a material having such a refractive index and an extinction coefficient that a value of the normalized evaluation function of the absorber film 4 is 1.015 or more can be relatively easily obtained.

In the reflective mask blank 100 of the present embodiment, the material of the absorber film 4 preferably contains iridium (Ir) and at least one selected from the group consisting of boron (B), silicon (Si), ruthenium (Ru), tantalum (Ta), and oxygen (O). In a case of the absorber film 4 containing an Ir simple substance, there is a problem that a surface is rough and etching is relatively not easy. The Ir thin film also has a problem that the refractive index (n) and the extinction coefficient (k) change depending on film formation conditions. Therefore, it is preferable to use an Ir alloy or an Ir compound containing the above-described elements as the material of the absorber film 4.

In the reflective mask blank 100 of the present embodiment, the material of the absorber film 4 preferably contains platinum (Pt) or gold (Au).

Platinum (Pt) has a refractive index of 0.891 and an extinction coefficient of 0.060. Gold (Au) has a refractive index of 0.899 and an extinction coefficient of 0.052. Therefore, by inclusion of platinum (Pt) or gold (Au) in the material of the absorber film 4, a material having such a refractive index and an extinction coefficient that a value of the normalized evaluation function of the absorber film 4 is 1.015 or more can be relatively easily obtained. In addition, platinum (Pt) or gold (Au) is a stable metal, and the refractive index thereof and the extinction coefficient thereof hardly change after film formation. Therefore, the material of the absorber film 4 preferably contains platinum (Pt) or gold (Au).

The absorber film 4 can include two layers of a buffer layer formed in contact with a surface of the multilayer reflective film 2 or the protective film 3, and an absorption layer formed on a surface of the buffer layer. In this case, the above-described material of the absorber film 4 can be used as a material of the absorption layer. The buffer layer can be formed when an etching selective ratio between the material of the absorption layer (absorber film 4) and the material of the multilayer reflective film 2 or the protective film 3 is not high. By forming the buffer layer, the absorber pattern 4a is easily formed, and therefore the absorber pattern 4a can be thinned. The above-described material of the absorber film 4 can be used as a material of the buffer layer. At this time, the material of the buffer layer is preferably a material having an etching selective ratio to the material of the absorption layer of 1.5 or more. By using the above-described material of the absorber film 4 as the buffer layer, it is possible to widen the range of selection of the materials of the absorption layer and the protective film 3 without reducing the effect of the present disclosure. For example, as the material of the buffer layer, a material containing chromium (Cr) and one or more elements selected from the group consisting of oxygen (O), nitrogen (N), carbon (C), boron (B), and hydrogen (H) may be used.

In addition, as the material of the buffer layer, a material other than the above-described material of the absorber film 4 can be used as long as the effect of the present disclosure is not reduced. For example, as the material of the buffer layer, a material containing tantalum (Ta) or silicon (Si) and one or more elements selected from the group consisting of oxygen (O), nitrogen (N), carbon (C), boron (B), and hydrogen (H) may be used. In such a case, the film thickness of the buffer layer is preferably ⅓ or less of the film thickness of the entire absorber film (absorption layer and buffer layer). The film thickness of the buffer layer is preferably 20 nm or less, more preferably 15 nm or less, and still more preferably 10 nm or less. The film thickness of the buffer layer is preferably 2 nm or more.

In a case of the absorber film 4 for the purpose of absorbing EUV light, the film thickness thereof is set such that the reflectance for EUV light to the absorber film 4 is 2% or less, and preferably 1% or less. In addition, in order to suppress a shadowing effect, the film thickness of the absorber film 4 is required to be less than 60 nm and preferably 50 nm or less.

In addition, an oxide layer may be formed on a surface of the absorber film 4 (absorption layer in a case where the absorber film 4 includes two layers of a buffer layer and the absorption layer). An oxide layer is formed on the surface of the absorber film 4 (absorption layer), and cleaning resistance of the absorber pattern 4a of the obtained reflective mask 200 can be thereby improved. The thickness of the oxide layer is preferably 1.0 nm or more, and more preferably 1.5 nm or more. In addition, the thickness of the oxide layer is preferably 5 nm or less, and more preferably 3 nm or less. When the thickness of the oxide layer is less than 1.0 nm, the thickness of the oxide layer is too thin and no effect can be expected. When the thickness of the oxide layer exceeds 5 nm, an influence on a surface reflectance for mask inspection light is large, and it is difficult to perform control for obtaining s predetermined surface reflectance.

Examples of a method for forming the oxide layer include subjecting the mask blank after the absorber film 4 (absorption layer) is formed to hot water treatment, ozone water treatment, heating treatment in an oxygen-containing gas, ultraviolet irradiation treatment in an oxygen-containing gas, O₂ plasma treatment, and the like. In addition, when the surface of the absorber film 4 (absorption layer) is exposed to the atmosphere after the absorber film 4 (absorption layer) is formed, an oxide layer may be formed on a surface layer by natural oxidation. In particular, in some cases, an oxide layer having a film thickness of 1 to 2 nm is formed.

«Etching Mask Film»

The reflective mask blank 100 of the present embodiment can include an etching mask film. The etching mask film has a film thickness of 0.5 nm or more and 14 nm or less.

By inclusion of an appropriate etching mask film, it is possible to provide the reflective mask blank 100 capable of reducing a shadowing effect of the reflective mask 200 and forming the fine and highly accurate absorber pattern 4a.

As illustrated in FIG. 1, the etching mask film is formed on the absorber film 4. As a material of the etching mask film, a material having a high etching selective ratio of the absorber film 4 to the etching mask film is used. Here, the expression “etching selective ratio of B to A” means a ratio of an etching rate of B that is a layer desired to be etched to an etching rate of A that is a layer not desired to be etched (layer serving as a mask). Specifically, “etching selective ratio of B to A” is specified by a formula of “etching selective ratio of B to A=etching rate of B/etching rate of A”. In addition, the expression “high selective ratio” means that a value of the selective ratio defined above is large as compared with that of an object for comparison. The etching selective ratio of the absorption layer 44 to the etching mask film is preferably 1.5 or more, and more preferably 3 or more.

In the reflective mask blank 100 of the present embodiment, the material of the etching mask film is preferably a material containing tantalum (Ta) and one or more elements selected from the group consisting of oxygen (O), nitrogen (N), carbon (C), boron (B), and hydrogen (H). In addition, the material of the etching mask film is preferably a material containing tantalum (Ta) and one or more elements selected from the group consisting of oxygen (O), nitrogen (N), boron (B), and hydrogen (H).

As the material of the etching mask film of the present embodiment, a material containing silicon can be used. The material containing silicon is a material of silicon, a silicon compound, metal silicon containing silicon and a metal, or a metal silicon compound containing a silicon compound and a metal, and the material of the silicon compound is preferably a material containing silicon and at least one element selected from the group consisting of oxygen (O), nitrogen (N), carbon (C), and hydrogen (H). In addition, among the materials of the etching mask film, the material of the silicon compound is more preferably a material containing silicon and at least one element selected from oxygen (O) and nitrogen (N).

Specific examples of the material containing silicon include SiO, SiN, SiON, SiC, SiCO, SiCN, SiCON, MoSi, MoSiO, MoSiN, MoSiON, and the like. SiO, SiN, or SiON is preferably used as the material containing silicon. Note that the material can contain a metalloid or a metal other than silicon within a range in which the effects of the present disclosure can be obtained. In addition, molybdenum silicide can be used as the metal silicon compound.

The etching mask film formed of a material containing silicon can be etched with a fluorine-based gas.

The film thickness of the etching mask film is 0.5 nm or more, preferably 1 nm or more, more preferably 2 nm or more, and still more preferably 3 nm or more from a viewpoint of obtaining a function as an etching mask for accurately forming a transfer pattern on the absorber film 4. In addition, the film thickness of the etching mask film is 14 nm or less, preferably 12 nm or less, and more preferably 10 nm or less from a viewpoint of reducing the film thickness of the resist film 11.

When the absorber film 4 includes two layers of a buffer layer and an absorption layer, the etching mask film and the buffer layer may be formed of the same material. In addition, the etching mask film and the buffer layer may be formed of materials containing the same metal and having different composition ratios. When the etching mask film and the buffer layer each contain tantalum, the tantalum content of the etching mask film may be larger than the tantalum content of the buffer layer, and the film thickness of the etching mask film may be larger than the film thickness of the buffer layer. When the etching mask film and the buffer layer each contain hydrogen, the hydrogen content of the etching mask film may be larger than the hydrogen content of the buffer layer.

«Resist Film 11»

The reflective mask blank 100 of the present embodiment can include the resist film 11 on the etching mask film. The reflective mask blank 100 of the present embodiment also includes a form including the resist film 11. In the reflective mask blank 100 of the present embodiment, by selecting the absorber film 4 containing an appropriate material and/or having an appropriate film thickness and an etching gas, the resist film 11 can also be thinned.

As a material of the resist film 11, for example, a chemically-amplified resist (CAR) can be used. By patterning the resist film 11 and etching the absorber film 4 (buffer layer 42 and absorption layer 44), the reflective mask 200 having a predetermined transfer pattern can be manufactured.

«Conductive Back Film 5»

The conductive back film 5 for electrostatic chuck is generally formed on the second main surface (back surface) side of the substrate 1 (side opposite to the multilayer reflective film 2 forming surface). An electrical characteristic (sheet resistance) required for the conductive back film 5 for electrostatic chuck is usually 100Ω/□ (Ω/square) or less. The conductive back film 5 can be formed, for example, by a magnetron sputtering method or an ion beam sputtering method using a target of a metal such as chromium or tantalum or an alloy thereof.

The material containing chromium (Cr) for the conductive back film 5 is preferably a Cr compound containing Cr and at least one selected from the group consisting of boron, nitrogen, oxygen, and carbon. Examples of the Cr compound include CrN, CrON, CrCN, CrCON, CrBN, CrBON, CrBCN, CrBOCN, and the like.

As the material containing tantalum (Ta) for the conductive back film 5, it is preferable to use Ta (tantalum), an alloy containing Ta, or a Ta compound containing either of Ta or an alloy containing Ta and at least one selected from the group consisting of boron, nitrogen, oxygen, and carbon. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like.

As the material containing tantalum (Ta) or chromium (Cr), the amount of nitrogen (N) present in a surface layer thereof is preferably small. Specifically, the nitrogen content in the surface layer of the conductive back film 5 of the material containing tantalum (Ta) or chromium (Cr) is preferably less than 5 atomic %, and more preferably, the surface layer contains substantially no nitrogen. This is because in the conductive back film 5 of the material containing tantalum (Ta) or chromium (Cr), the lower the nitrogen content in the surface layer is, the higher wear resistance is.

The conductive back film 5 preferably contains a material containing tantalum and boron. The conductive back film 5 contains a material containing tantalum and boron, and a conductive film 23 having wear resistance and chemical resistance can be thereby obtained. When the conductive back film 5 contains tantalum (Ta) and boron (B), the content of B is preferably 5 to 30 atomic %. A ratio between Ta and B (Ta:B) in a sputtering target used for forming the conductive back film 5 is preferably from 95:5 to 70:30.

The film thickness of the conductive back film 5 is not particularly limited as long as a function of the conductive back film 5 for electrostatic chuck is satisfied. The film thickness of the conductive back film 5 is usually from 10 nm to 200 nm. In addition, the conductive back film 5 further adjusts a stress on the second main surface side of the reflective mask blank 100. That is, the conductive back film 5 is adjusted such that the flat reflective mask blank 100 can be obtained in balance with a stress from various films formed on the first main surface side.

<Reflective Mask 200 and Method for Manufacturing the Same>

The present embodiment is the reflective mask 200 having the absorber pattern 4a in which the absorber film 4 of the above-described reflective mask blank 100 is partnered. By using the reflective mask 200 of the present embodiment, it is possible to form a transfer pattern of diversified fine pattern shapes formed on a transferred substrate and to perform EUV exposure with a high throughput.

The absorber pattern 4a of the reflective mask 200 can absorb EUV light and reflect the EUV light at an opening of the absorber pattern 4a. Therefore, by irradiating the reflective mask 200 with EUV light using a predetermined optical system, a predetermined fine transfer pattern can be transferred onto a transferred object.

The reflective mask 200 is manufactured using the reflective mask blank 100 of the present embodiment. Here, only an outline will be described, and a detailed description will be given below in Examples with reference to the drawings.

The reflective mask blank 100 is prepared. The resist film 11 is formed on the absorber film 4 on the first main surface of the reflective mask blank 100 (this is not necessary in a case where the resist film 11 is included as the reflective mask blank 100). A desired pattern is drawn (exposed) on the resist film 11 and further developed and rinsed to form a predetermined resist pattern 11a.

In the case of the reflective mask blank 100, the absorber pattern 4a is formed by etching the absorber film 4 using the resist pattern 11a as a mask. The resist pattern 11a is peeled off by oxygen ashing or wet treatment with hot sulfuric acid or the like. Finally, wet cleaning is performed using an acidic or alkaline aqueous solution.

Through the above steps, the reflective mask 200 of the present embodiment can be obtained.

<Method for Manufacturing Semiconductor Device>

A method for manufacturing a semiconductor device of the present embodiment includes a step of setting the reflective mask 200 of the present embodiment in an exposure apparatus including an exposure light source that emits EUV light, and transferring a transfer pattern onto a resist layer formed on a transferred substrate. By the method for manufacturing a semiconductor device of the present embodiment, diversified fine pattern shapes can be formed on a transferred substrate with a high throughput.

According to the method for manufacturing a semiconductor device of the present embodiment, by using the reflective mask 200 of the present embodiment, it is possible to form a transfer pattern of diversified fine pattern shapes formed on a transferred substrate. In addition, by using the reflective mask 200 of the present embodiment, EUV exposure can be performed with a high throughput.

By performing EUV exposure using the reflective mask 200 of the present embodiment, a desired transfer pattern can be formed on a semiconductor substrate with high dimensional accuracy and a high throughput. Through various steps such as etching of a film to be processed, formation of an insulating film and a conductive film, introduction of a dopant, and annealing in addition to this lithography step, it is possible to manufacture a semiconductor device in which a desired electronic circuit is formed.

More specifically, an EUV exposure apparatus includes a laser plasma light source that generates EUV light, an illumination optical system, a mask stage system, a reduction projection optical system, a wafer stage system, vacuum equipment, and the like. The light source includes a debris trap function, a cut filter that cuts light having a long wavelength other than exposure light, equipment for vacuum differential pumping, and the like. The illumination optical system and the reduction projection optical system each include a reflection mirror. The reflective mask 200 for EUV exposure is electrostatically attracted by a conductive film formed on the second main surface of the reflective mask 200 and is mounted on a mask stage.

Light of the EUV light source is emitted to the reflective mask 200 through the illumination optical system at an angle tilted by 6° to 8° with respect to a vertical plane of the reflective mask 200. Reflected light from the reflective mask 200 with respect to this incident light is reflected (regularly reflected) in a direction opposite to an incident direction at the same angle as an incident angle, guided to a reflective projection system usually having a reduction ratio of ¼, and exposed on a resist layer on a wafer (semiconductor substrate) mounted on a wafer stage. During this time, at least a place through which EUV light passes is evacuated. In addition, when this exposure is performed, mainstream exposure is scan exposure in which a mask stage and a wafer stage are synchronously scanned at a rate corresponding to a reduction ratio of the reduction projection optical system, and exposure is performed through a slit. Then, by developing the exposed resist of the resist layer, a resist transfer pattern can be formed on the semiconductor substrate. Then, by performing etching or the like using this resist transfer pattern as a mask, a predetermined wiring pattern can be formed, for example, on the semiconductor substrate. Through such an exposure step, a step of processing a film to be processed, a step of forming an insulating film and a conductive film, a dopant introduction step, an annealing step, and other necessary steps, the semiconductor device is manufactured.

### EXAMPLES

Hereinafter, Examples will be described with reference to the drawings. Note that in Examples, the same reference sign will be used for similar constituent elements, and description thereof will be simplified or omitted.

### Example 1

As Example 1, the effect of the present embodiment was confirmed by the following simulation. Note that the following refractive index (n) and extinction coefficient (k) are values for light having a wavelength of 13.5 nm. The same applies to other Examples and the like.

In the simulation of Example 1, the structure of a reflective mask 200 illustrated in FIG. 2D was used. That is, the reflective mask 200 has a structure in which a multilayer reflective film 2, a protective film 3, and an absorber pattern 4a are included in this order on one main surface of a substrate 1. The reflective mask 200 includes a conductive back film 5 on the other main surface of the substrate 1. Note that, in the simulation of Example 1, since exposure light is reflected by the multilayer reflective film 2, presence or absence of the conductive back film 5 does not affect a result of the simulation.

In the simulation of Example 1, a SiO₂—TiO₂-based glass substrate that is a low thermal expansion glass substrate having a 6025 size (about 152 mm×152 mm×6.35 mm) and having both a first main surface and a second main surface (back surface) polished was used as the substrate 1. The two main surfaces of the substrate 1 were assumed to be main surfaces equivalent to those polished by a rough polishing step, a fine polishing step, a local processing step, and a touch polishing step such that the main surfaces were flat and smooth.

The conductive back film 5 was a thin film formed of a CrN film and having a film thickness of 20 nm. Specifically, the conductive back film 5 was assumed to be a thin film equivalent to that obtained by forming the conductive back film 5 formed of a CrN film on the second main surface (back surface) of the substrate 1 by a magnetron sputtering (reactive sputtering) method under the following conditions.

Conditions for forming conductive back film 5: a Cr target, a mixed gas atmosphere of Ar and N₂ (Ar: 90%, N: 10%), and a film thickness of 20 nm.

The multilayer reflective film 2 was the periodic multilayer reflective film 2 containing Mo and Si in order to make the multilayer reflective film 2 suitable for EUV light having a wavelength of 13.5 nm. Specifically, the multilayer reflective film 2 was assumed to be a multilayer film equivalent to the multilayer reflective film 2 formed by alternately building up a Mo layer and a Si layer on a main surface (first main surface) of the substrate 1 opposite to the side where the conductive back film 5 was formed using a Mo target and a Si target in an Ar gas atmosphere by an ion beam sputtering method. In this multilayer film, first, a Si film was formed so as to have a film thickness of 4.2 nm, and then a Mo film was formed so as to have a film thickness of 2.8 nm. This stack is counted as one period, the stack of a Si film and a Mo film was built up for 40 periods in a similar manner, and finally, a Si film was formed so as to have a film thickness of 4.0 nm to form the multilayer reflective film 2. The multilayer reflective film 2 was assumed to be the multilayer reflective film 2 of Example 1.

Simulation was performed assuming that the protective film 3 was either one of the following two types thin films.
Example 1-1: RuNb film (n=0.9016, k=0.0131, film thickness 3.5 nm)
Example 1-2: RuRh film (n=0.8898, k=0.0155, film thickness 3.5 nm)

A simulation was performed on a case where the absorber pattern 4a had the following three types of patterns.
(1) vertical L/S patterns (Vertical L/S, hp=16 nm),
(2) horizontal L/S pattern (Horizontal L/S, hp=16 nm),
(3) contact hole pattern (Contact Hole, diameter: 24 nm)

In an exposure step, light of the EUV light source is emitted to the reflective mask 200 through the illumination optical system at an angle tilted by 6° to 8° with respect to a vertical plane of the reflective mask 200. Reflected light from the reflective mask 200 with respect to this incident light is reflected (regularly reflected) in a direction opposite to an incident direction at the same angle as an incident angle Therefore, even in the same L/S pattern, when the direction of the L/S pattern with respect to a plane including the incident light and the reflected light is different, a transfer pattern transferred onto the transferred substrate is also different. A case where a normal line of a plane including the incident light and the reflected light with respect to the reflective mask 200 is vertical to a direction of a line of the L/S pattern is a vertical L/S pattern, and a case where a normal line of a plane including the incident light and the reflected light with respect to the reflective mask 200 is parallel to a direction of a line of the L/S pattern is a horizontal L/S pattern.

The contact hole pattern is circular. Therefore, when the absorber pattern 4a of the reflective mask 200 is the contact hole pattern, a transfer pattern transferred onto the transferred substrate does not depend on the direction of the incident light.

Note that the film thickness of the absorber pattern 4a was optimized such that each of the above three types of patterns has the highest value of the evaluation function.

As the reflective mask 200 for normalizing values of the evaluation function of the reflective masks 200 of Examples 1-1 and 1-2, the reflective mask 200 of a thin film in which the absorber film 4 is optically equivalent to a TaBN film and a TaN film was used. That is, the absorber film 4 of the reflective mask 200 for normalization is a film having a refractive index of 0.95 and an extinction coefficient of 0.03 for EUV light having a wavelength of 13.5 nm. The values of the evaluation function of the reflective masks 200 of Examples 1-1 and 1-2 were normalized with the value of the evaluation function of the reflective mask 200 for normalization as 1. The same applies to Examples and the like other than Examples 1-1 and 1-2.

### Example 1-1

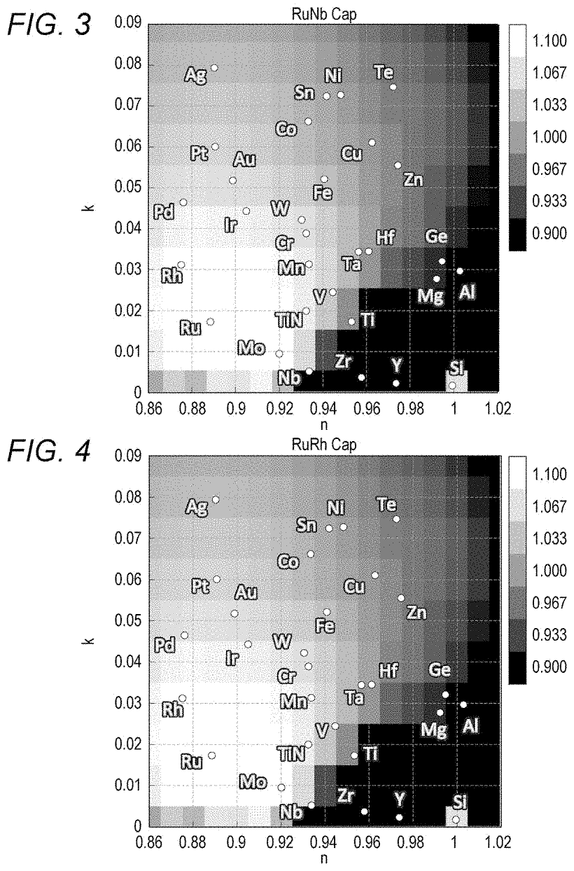

FIG. 3 illustrates a value of the normalized evaluation function obtained by simulation in a case where the absorber pattern 4a is a vertical line and space (L/S) pattern having a hp of 16 nm for the reflective mask 200 of Example 1-1 (the protective film 3 is a RuNb film). FIG. 3 is a diagram illustrating a distribution of values of the normalized evaluation function when predetermined incident light is emitted to absorber patterns 4a having different refractive indexes (n) and extinction coefficients (k) in the reflective mask 200 of Example 1-1. In the simulation illustrated in FIG. 3, a large number of simulations were performed assuming the absorber films 4 having a large number of combinations of the refractive index (n) and the extinction coefficient (k) in the range illustrated in FIG. 3. In FIG. 3, the value of the normalized evaluation function is illustrated in gray scale.

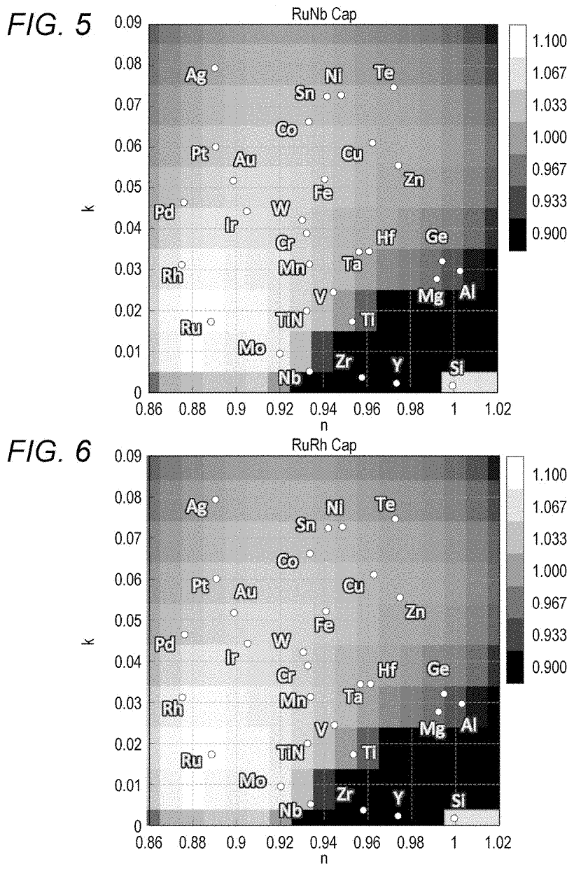

FIG. 5 illustrates a value of the normalized evaluation function obtained by simulation in a case where the absorber pattern 4a is a horizontal line and space (L/S) pattern having a hp of 16 nm for the reflective mask 200 of Example 1-1 (the protective film 3 is a RuNb film). FIG. 5 is a diagram illustrating a distribution of values of the normalized evaluation function when predetermined incident light is emitted to absorber patterns 4a having different refractive indexes (n) and extinction coefficients (k) in the reflective mask 200 of Example 1-1. In the simulation illustrated in FIG. 5, a large number of simulations were performed assuming the absorber films 4 having a large number of combinations of the refractive index (n) and the extinction coefficient (k) in the range illustrated in FIG. 5. In FIG. 5, the value of the normalized evaluation function is illustrated in gray scale.

FIG. 7 illustrates a value of the normalized evaluation function obtained by simulation in a case where the absorber pattern 4a is a contact hole pattern (diameter: 24 nm) for the reflective mask 200 of Example 1-1 (the protective film 3 is a RuNb film). FIG. 7 is a diagram illustrating a distribution of values of the normalized evaluation function when predetermined incident light is emitted to absorber patterns 4a having different refractive indexes (n) and extinction coefficients (k) in the reflective mask 200 of Example 1-1. In the simulation illustrated in FIG. 7, a large number of simulations were performed assuming the absorber films 4 having a large number of combinations of the refractive index (n) and the extinction coefficient (k) in the range illustrated in FIG. 7. In FIG. 7, the value of the normalized evaluation function is illustrated in gray scale.

### Example 1-2

FIG. 4 illustrates a value of the normalized evaluation function obtained by simulation in a case where the absorber pattern 4a is a vertical line and space (L/S) pattern having a hp of 16 nm for the reflective mask 200 of Example 1-2 (the protective film 3 is a RuRh film). Similarly to the case of Example 1-1 illustrated in FIG. 3, FIG. 4 is a diagram illustrating a distribution of values of the normalized evaluation function when predetermined incident light is emitted to absorber patterns 4a having different refractive indexes (n) and extinction coefficients (k) in the reflective mask 200 of Example 1-2.

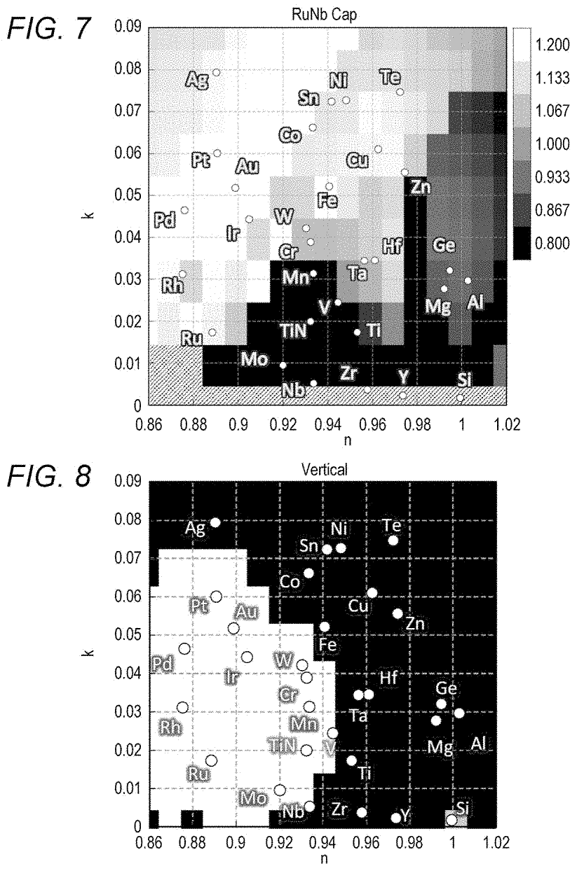

FIG. 6 illustrates a value of the normalized evaluation function obtained by simulation in a case where the absorber pattern 4a is a horizontal line and space (L/S) pattern having a hp of 16 nm for the reflective mask 200 of Example 1-2 (the protective film 3 is a RuRh film). Similarly to the case of Example 1-1 illustrated in FIG. 5, FIG. 6 is a diagram illustrating a distribution of values of the normalized evaluation function when predetermined incident light is emitted to absorber patterns 4a having different refractive indexes (n) and extinction coefficients (k) in the reflective mask 200 of Example 1-2.

### Combination of Examples 1-1 and 1-2

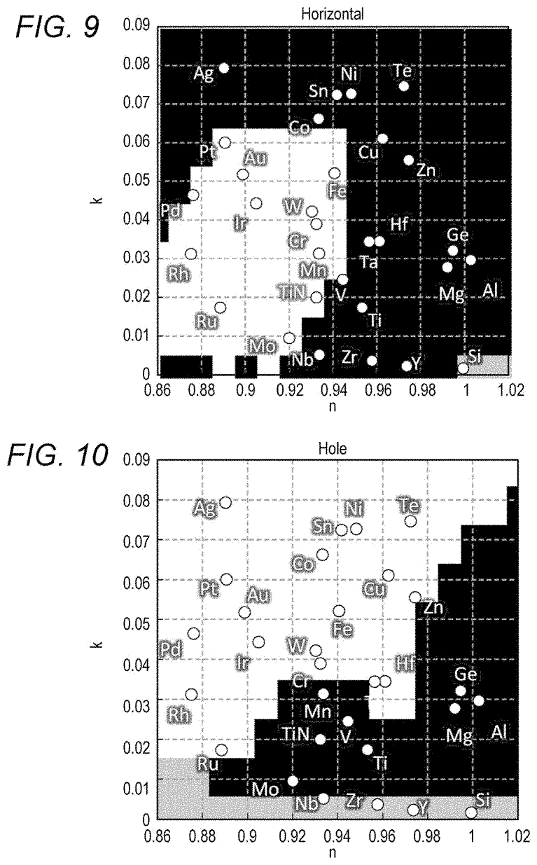

FIGS. 8 and 9 illustrate a combination of distributions of values of the normalized evaluation function of Examples 1-1 and 1-2 obtained as described above. That is, FIG. 8 is a diagram combining distributions of values of the normalized evaluation function of the vertical L/S patterns illustrated in FIGS. 3 (Example 1-1) and 4 (Example 1-2), and is a diagram illustrating a distribution obtained by binarizing the combined distribution into a case where values of the normalized evaluation function illustrated in FIGS. 3 and 4 are both 1.015 or more (white) and the other cases (black). FIG. 9 is a diagram combining distributions of values of the normalized evaluation function of the horizontal L/S patterns illustrated in FIGS. 5 (Example 1-1) and 6 (Example 1-2), and is a diagram illustrating a distribution obtained by binarizing the combined distribution into a case where values of the normalized evaluation function illustrated in FIGS. 5 and 6 are both 1.015 or more (white) and the other cases (black). FIG. 10 is a diagram illustrating a distribution of values of the normalized evaluation function of the contact hole pattern illustrated in FIG. 7 (Example 1-1), binarized into a case where a value of the evaluation function of the contact hole pattern in Example 1-1 is 1.015 or more (white) and the other cases (black).

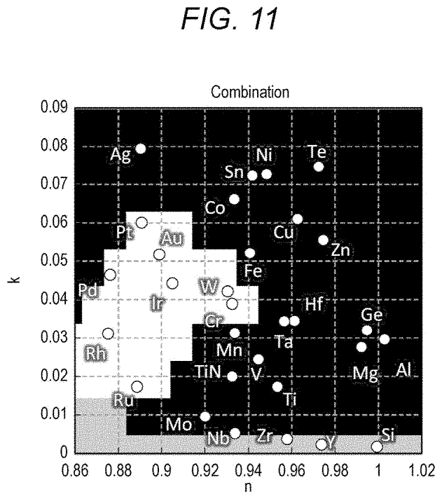

FIG. 11 is a diagram combining the binarized distributions of values of the normalized evaluation function illustrated in FIGS. 8 to 10. FIG. 11 illustrates a distribution of a case where values of the normalized evaluation function illustrated in FIGS. 8 to 10 are all 1.015 or more (white) and the other cases (black).

From the above results of the simulations of Examples 1-1 and 1-2, it can be understood that in the distribution of the refractive index (n) and the extinction coefficient (k) of the absorber pattern 4a (absorber film 4), the area in which values of the normalized evaluation function are all 1.015 or more is an area indicated as white in FIG. 11. Examples of a material of a simple substance belonging to an area where values of the normalized evaluation function are all 1.015 or more include Ag, Co, Pt, Au, Fe, Pd, Ir, W, Cr, Rh, Ru, and the like. Therefore, when the absorber film 4 is formed using these materials, it can be said that it is possible to form a transfer pattern of diversified fine pattern shapes formed on a transferred substrate, and it is possible to obtain the reflective mask blank 100 for manufacturing the reflective mask 200 capable of forming a transfer pattern of diversified fine pattern shapes formed on a transferred substrate and having a transfer pattern capable of performing EUV exposure with a high throughput as compared with the conventional absorber film 4 containing a TaBN film, a TaN film, or the like.

In addition, even with a material other than the above material of the simple substance, it can be said that the absorber pattern 4a (absorber film 4) having a refractive index (n) and an extinction coefficient (k) of the area indicated as white in FIG. 11 (area where values of the normalized evaluation function are all 1.015 or more) can be formed by appropriately adjusting the composition as long as the material is an alloy material or a compound material. Note that examples of such an alloy material or compound material include an alloy material or a compound material of iridium (Ir) with boron (B), silicon (Si), ruthenium (Ru), tantalum (Ta), or oxygen (O).

Note that it can be said that as the value of the normalized evaluation function is higher, it is possible to form a better transfer pattern and EUV exposure can be performed with a higher throughput as compared with the conventional absorber film 4 containing a TaBN film, a TaN film, or the like. Therefore, the value of the normalized evaluation function is preferably 1.015 or more, more preferably 1.03 or more, still more preferably 1.05 or more.

### Example 2

As Example 2, a reflective mask blank 100 and a reflective mask 200 were manufactured by selecting a material of an absorber film 4 in which the value of the normalized evaluation function is 1.015 or more.

As illustrated in FIG. 1, the reflective mask blank 100 of Example 2 includes a conductive back film 5, a substrate 1, a multilayer reflective film 2, a protective film 3, and the absorber film 4. As illustrated in FIG. 2A, a resist film 11 is formed on the absorber film 4. FIGS. 2A to 2D are main part schematic cross-sectional views illustrating a process for manufacturing the reflective mask 200 from the reflective mask blank 100.

In the following description, the elemental composition of a deposited thin film was measured by Rutherford backscattering spectrometry.

First, the reflective mask blank 100 of Example 2 will be described.

A SiO₂—TiO₂-based glass substrate that is a low thermal expansion glass substrate having a 6025 size (about 152 mm×152 mm×6.35 mm) and having both main surfaces that are a first main surface and a second main surface polished was prepared as the substrate 1. The main surfaces were subjected to polishing including a rough polishing step, a precision polishing step, a local processing step, and a touch polishing step such that the main surfaces were flat and smooth.

The conductive back film 5 formed of a CrN film was formed on the second main surface (back surface) of the SiO₂—TiO₂-based glass substrate 1 by a magnetron sputtering (reactive sputtering) method under the following conditions.

Conditions for forming conductive back film 5: a Cr target, a mixed gas atmosphere of Ar and N₂ (Ar: 90%, N: 10%), and a film thickness of 20 nm.

Next, the multilayer reflective film 2 was formed on the main surface (first main surface) of the substrate 1 on a side opposite to a side where the conductive back film 5 was formed. The multilayer reflective film 2 formed on the substrate 1 was a periodic multilayer reflective film 2 containing Mo and Si in order to make the multilayer reflective film 2 suitable for EUV light having a wavelength of 13.5 nm. The multilayer reflective film 2 was formed by alternately building up a Mo layer and a Si layer on the substrate 1 by an ion beam sputtering method in an Ar gas atmosphere using a Mo target and a Si target. First, a Si film was formed so as to have a film thickness of 4.2 nm, and then a Mo film was formed so as to have a film thickness of 2.8 nm. This stack is counted as one period, the stack of a Si film and a Mo film was built up for 40 periods in a similar manner, and finally, a Si film was formed so as to have a film thickness of 4.0 nm to form the multilayer reflective film 2.

Subsequently, the protective film 3 formed of a RuNb film was formed so as to have a thickness of 3.5 nm in an Ar gas atmosphere by an ion beam sputtering method using a RuNb target.

Next, the absorber film 4 including a buffer layer containing CrON and an absorption layer containing IrTaO was formed on the protective film 3.

Specifically, first, the buffer layer formed of a CrON film was formed by a DC magnetron sputtering method. The CrON film was formed so as to have a film thickness of 6 nm by reactive sputtering in a mixed gas atmosphere of an Ar gas, an O₂ gas, and a N₂ gas using a Cr target. The CrON film (buffer layer) had a refractive index (n) of 0.930 and an extinction coefficient (k) of 0.039 at a wavelength of 13.5 nm.

Next, the absorption layer formed of an IrTaO film was formed by a DC magnetron sputtering method. The IrTaO film was formed so as to have a film thickness of 40 nm by reactive sputtering in a mixed gas atmosphere of a Xe gas and an O₂ gas using an IrTa alloy target.

An element ratio of the IrTaO film was 49.5 atomic % for Ir, 3.4 atomic % for Ta, and 47.1 atomic % for 0. The IrTaO film had a refractive index (n) of 0.927 and an extinction coefficient (k) of 0.033 at a wavelength of 13.5 nm.

As described above, the reflective mask blank 100 of Example 2 was manufactured.

Next, using the above reflective mask blank 100 of Example 2, the reflective mask 200 of Example 2 was manufactured.

The resist film 11 was formed so as to have a thickness of 80 nm on the absorber film 4 (absorption layer) of the reflective mask blank 100 (FIG. 2A). A chemically amplified resist (CAR) was used for forming the resist film 11. A desired pattern was drawn (exposed) on this resist film 11, and further developed and rinsed to form the predetermined resist pattern 11a (FIG. 2B). Next, using the resist pattern 11a as a mask, dry etching of the IrTaO film (absorption layer) was performed using a mixed gas of a CF₄ gas and an O₂ gas (CF₄+O₂ gas), and subsequently dry etching of the CrON film (buffer layer) was performed using a mixed gas of a Cl₂ gas and an O₂ gas (Cl₁+O₂ gas) to form the absorber pattern 4a (FIG. 2C).

Thereafter, the resist pattern 11a was peeled off by oxygen ashing (FIG. 2D). Finally, wet cleaning was performed with deionized water (DIW) to manufacture the reflective mask 200 of Example 2.

Note that a mask defect inspection can be performed as necessary after wet cleaning, and a mask defect can be corrected appropriately.

The reflective mask 200 of Example 2 was set in an EUV scanner, and EUV exposure was performed on a wafer on which a film to be processed and a resist layer were formed on a semiconductor substrate. Then, by developing the exposed resist of the resist layer, a resist transfer pattern was formed on the semiconductor substrate on which the film to be processed was formed.

Note that, separately, when a predetermined chemically amplified resist (CAR) was exposed to predetermined exposure light, a normalized image log slope (NILS) and a threshold of light intensity for exposure of the predetermined resist to light in a case of use of the reflective mask 200 of Example 2 were measured, and a value of the evaluation function was obtained as a product thereof. When the value of the evaluation function was normalized with a value of the evaluation function in a case where the reflective mask 200 of Reference Example 1 described later was used, the value of the normalized evaluation function in Example 2 was 1.03.

It has been confirmed that, by forming a resist transfer pattern on the transferred substrate 1 using the reflective mask 200 of Example 2, it is possible to form a transfer pattern of diversified fine pattern shapes formed on the transferred substrate and to perform EUV exposure with a high throughput.

This resist transfer pattern was transferred onto the film to be processed by etching, and through various steps such as formation of an insulating film and a conductive film, introduction of a dopant, and annealing, a semiconductor device having desired characteristics could be manufactured.

### Example 3

In Example 3, a reflective mask blank 100 and a reflective mask 200 were manufactured in a similar manner to Example 1 except that a RuRh film having a film thickness of 3.5 nm was used as a protective film 3 and a Pt film was used as an absorption layer in an absorber film 4. Therefore, the absorber film 4 of Example 3 includes a buffer layer (film thickness: 6 nm) containing CrON and an absorption layer (film thickness: 40 nm) of a Pt film.

Note that the Pt film had a refractive index (n) of 0.889 and an extinction coefficient (k) of 0.059 at a wavelength of 13.5 nm.

The reflective mask 200 of Example 3 was set in an EUV scanner, and EUV exposure was performed on a wafer on which a film to be processed and a resist layer were formed on a semiconductor substrate. Then, by developing the exposed resist of the resist layer, a resist transfer pattern was formed on the semiconductor substrate on which the film to be processed was formed.

Note that, separately, when a predetermined chemically amplified resist (CAR) was exposed to predetermined exposure light, a normalized image log slope (NILS) and a threshold of light intensity for exposure of the predetermined resist to light in a case of use of the reflective mask 200 of Example 3 were measured, and a value of the evaluation function was obtained as a product thereof. When the value of the evaluation function was normalized with a value of the evaluation function in a case where the reflective mask 200 of Reference Example 1 described later was used, the value of the normalized evaluation function in Example 3 was 1.02.

It has been confirmed that, by forming a resist transfer pattern on the transferred substrate using the reflective mask 200 of Example 3, it is possible to form a transfer pattern of diversified fine pattern shapes formed on the transferred substrate and to perform EUV exposure with a high throughput.

### Example 4

As Example 4, a reflective mask blank 100 was manufactured in a similar manner to Example 1 except that an absorber film 4 included a buffer layer containing TaBO and an absorption layer containing RuCrN.

In the manufacture of the reflective mask blank 100 of Example 4, in a similar manner to Example 1, a conductive back film 5 formed of a CrN film was formed on a second main surface (back surface) of a substrate 1, and a multilayer reflective film 2 formed of Mo and Si and a protective film 3 formed of a RuNb film were formed on a main surface (first main surface) of the substrate 1.

Next, the absorber film 4 including a buffer layer containing TaBO and an absorption layer containing RuCrN was formed on the protective film 3.

Specifically, first, the buffer layer formed of a TaBO film was formed by a DC magnetron sputtering method. The TaBO film was formed so as to have a film thickness of 6 nm by reactive sputtering in a mixed gas atmosphere of an Ar gas and an O₂ gas using a TaB target. An element ratio of the TaBO film was 39 atomic % for Ta, 5 atomic % for B, and 56 atomic % for 0. The TaBO film (buffer layer) had a refractive index (n) of 0.955 and an extinction coefficient (k) of 0.022 at a wavelength of 13.5 nm.

Next, the absorption layer formed of a RuCrN film was formed by a DC magnetron sputtering method. The RuCrN film was formed so as to have a film thickness of 42 nm by reactive sputtering in a mixed gas atmosphere of a Kr gas and a N₂ gas using a RuCr target. An element ratio of the RuCrN film was 83 atomic % for Ru, 10 atomic % for Cr, and 7 atomic % for 0. The RuCrN film had a refractive index (n) of 0.900 and an extinction coefficient (k) of 0.021 at a wavelength of 13.5 nm.

As described above, the reflective mask blank 100 of Example 4 was manufactured.

Next, using the reflective mask blank 100 of Example 4, the reflective mask 200 of Example 4 was manufactured in a similar manner to Example 1 except that the etching gas of the RuCrN film was a mixed gas of a Cl₂ gas and an O₂ gas, and the etching gas of the TaBO film was a mixed gas of a CF₄ gas and a He gas.

The reflective mask 200 of Example 4 was set in an EUV scanner, and EUV exposure was performed on a wafer on which a film to be processed and a resist layer were formed on a semiconductor substrate. Then, by developing the exposed resist of the resist layer, a resist transfer pattern was formed on the semiconductor substrate on which the film to be processed was formed.

Note that, separately, when a predetermined chemically amplified resist (CAR) was exposed to predetermined exposure light, a normalized image log slope (NILS) and a threshold of light intensity for exposure of the predetermined resist to light in a case of use of the reflective mask 200 of Example 4 were measured, and a value of the evaluation function was obtained as a product thereof. When the value of the evaluation function was normalized with a value of the evaluation function in a case where the reflective mask 200 of Reference Example 1 described later was used, the value of the normalized evaluation function in Example 4 was 1.02.

It has been confirmed that, by forming a resist transfer pattern on the transferred substrate using the reflective mask 200 of Example 4, it is possible to form a transfer pattern of diversified fine pattern shapes formed on the transferred substrate and to perform EUV exposure with a high throughput.

### Reference Example 1

In Reference Example 1, a reflective mask blank 100 and a reflective mask 200 were manufactured in a similar manner to Example 1 except that a Ru film having a film thickness of 3.5 nm was used as a protective film 3 and a single layer TaBN film was used as an absorber film 4. The reflective mask 200 of Reference Example 1 is a reflective mask 200 serving as a reference for normalizing a value of the evaluation function.

In the manufacture of the reflective mask blank 100 of Reference Example 1, in a similar manner to Example 1, a conductive back film 5 formed of a CrN film was formed on a second main surface (back surface) of a substrate 1, and a multilayer reflective film 2 formed of Mo and Si was formed on a main surface (first main surface) of the substrate 1.

Subsequently, the protective film 3 formed of a Ru film was formed so as to have a film thickness of 3.5 nm in an Ar gas atmosphere by an ion beam sputtering method using a Ru target.

Next, the absorber film 4 was formed on the protective film 3. Specifically, the absorber film 4 formed of a TaBN film was formed by a DC magnetron sputtering method. The TaBN film was formed so as to have a film thickness of 55 nm by reactive sputtering in a mixed gas atmosphere of an Ar gas and a N₂ gas using a TaB mixed sintering target.

An element ratio of the absorber film 4 (TaBN film) of Reference Example 1 was 75 atomic % for Ta, 12 atomic % for B, and 13 atomic % for N. The absorber film 4 (TaBN film) had a refractive index (n) of 0.95 and an extinction coefficient (k) of 0.030 at a wavelength of 13.5 nm. Therefore, it can be said that the reflective mask blank 100 of Reference Example 1 includes the absorber film 4 suitable for manufacturing the reflective mask 200 serving as a reference for normalizing a value of the evaluation function.

As described above, the reflective mask blank 100 of Reference Example 1 was manufactured.

Next, a reflective mask 200 of Reference Example 1 was manufactured using the reflective mask blank 100 of Reference Example 1 in a similar manner to Example 2. Note that, at the time of dry etching of the absorber film 4 (TaBN film), the absorber pattern 4a was formed by performing dry etching of the TaBN film using a mixed gas of a CF₄ gas and a He gas (CF₄+He gas) (FIG. 2C).

The reflective mask 200 of Reference Example 1 was set in an EUV scanner, and EUV exposure was performed on a wafer on which a film to be processed and a resist layer were formed on a semiconductor substrate. Then, by developing the exposed resist of the resist layer, a resist transfer pattern was formed on the semiconductor substrate on which the film to be processed was formed.

Note that, separately, when a predetermined chemically amplified resist (CAR) was exposed to predetermined exposure light, a normalized image log slope (NILS) and a threshold of light intensity for exposure of the predetermined resist to light in a case of use of the reflective mask 200 of Reference Example 1 were measured, and a value of the evaluation function was obtained as a product thereof. With the value of the evaluation function as a reference, the value of the evaluation function in the case of using the reflective masks 200 of Examples 2 and 3 was normalized. That is, the value of the normalized evaluation function of Reference Example 1 is 1.

In Reference Example 1, since the reflective mask 200 has a value of the evaluation function as a reference, the value of the normalized evaluation function is 1. Therefore, when a resist transfer pattern is formed on a transferred substrate using the reflective mask 200 of Reference Example 1, it is clear that diversification and fineness of the pattern shape of the transfer pattern formed on the transferred substrate are low and an EUV exposure throughput is relatively low as compared with those of the reflective masks 200 of Examples 2 and 3.

### REFERENCE SIGNS LIST

1 Substrate
2 Multilayer reflective film
3 Protective film
4 Absorber film
4a Absorber pattern
5 Conductive back film
11 Resist film
11a Resist pattern
100 Reflective mask blank
200 Reflective mask

1. A reflective mask blank comprising: a substrate, a multilayer reflective film on the substrate and an absorber film on the multilayer reflective film, wherein
when normalization is performed with a value of an evaluation function of a film having a refractive index of 0.95 and an extinction coefficient of 0.03 for EUV light having a wavelength of 13.5 nm as 1, the absorber film comprises a material having such a refractive index and an extinction coefficient that a value of the normalized evaluation function of the absorber film is 1.015 or more, and
the evaluation function is a product of a normalized image log slope (NILS) and a threshold of light intensity for exposure of a predetermined resist to light.

2. The reflective mask blank according to claim 1, wherein the reflective mask blank is used to manufacture a reflective mask comprising a transfer pattern comprising a line and space of a LOGIC hp 16 nm generation or later.

3. The reflective mask blank according to claim 1, wherein the refractive index of the material of the absorber film for EUV light having a wavelength of 13.5 nm is within a range of 0.86 to 0.95, and the extinction coefficient of the material of the absorber film for EUV light having a wavelength of 13.5 nm is within a range of 0.015 to 0.065.

4. The reflective mask blank according to claim 1, wherein the material of the absorber film comprises at least one selected from iridium (Ir) and ruthenium (Ru).

5. The reflective mask blank according to claim 1, wherein the material of the absorber film comprises iridium (Ir) and at least one selected from the group consisting of boron (B), silicon (Si), ruthenium (Ru), tantalum (Ta), and oxygen (O).

6. The reflective mask blank according to claim 1, wherein the material of the absorber film comprises platinum (Pt).

7. The reflective mask blank according to claim 1, wherein the material of the absorber film comprises gold (Au).

8. The reflective mask blank according to claim 1, comprising a protective film between the multilayer reflective film and the absorber film, wherein
the protective film is formed of a material comprising ruthenium (Ru) or silicon (Si).

9. A reflective mask comprising: a substrate, a multilayer reflective film on the substrate and an absorber film which is patterned on the multilayer reflective film, wherein
when normalization is performed with a value of an evaluation function of a film having a refractive index of 0.95 and an extinction coefficient of 0.03 for EUV light having a wavelength of 13.5 nm as 1, the absorber film comprises a material having such a refractive index and an extinction coefficient that a value of the normalized evaluation function of the absorber film is 1.015 or more, and
the evaluation function is a product of a normalized image log slope (NILS) and a threshold of light intensity for exposure of a predetermined resist to light.

10. A method for manufacturing a semiconductor device, the method comprising setting the reflective mask according to claim 9 in an exposure apparatus comprising an exposure light source that emits EUV light and transferring a transfer pattern onto a resist layer formed on a transferred substrate.

11. The reflective mask according to claim 9, wherein the reflective mask comprising a transfer pattern comprising a line and space of a LOGIC hp 16 nm generation or later.

12. The reflective mask according to claim 9, wherein the refractive index of the material of the absorber film for EUV light having a wavelength of 13.5 nm is within a range of 0.86 to 0.95, and the extinction coefficient of the material of the absorber film for EUV light having a wavelength of 13.5 nm is within a range of 0.015 to 0.065.

13. The reflective mask according to claim 9, wherein the material of the absorber film comprises at least one selected from iridium (Ir) and ruthenium (Ru).

14. The reflective mask according to claim 9, wherein the material of the absorber film comprises iridium (Ir) and at least one selected from the group consisting of boron (B), silicon (Si), ruthenium (Ru), tantalum (Ta), and oxygen (O).

15. The reflective mask according to claim 9, wherein the material of the absorber film comprises platinum (Pt).

16. The reflective mask according to claim 9, wherein the material of the absorber film comprises gold (Au).

17. The reflective mask according to claim 9, comprising a protective film between the multilayer reflective film and the absorber film, wherein
the protective film is formed of a material comprising ruthenium (Ru) or silicon (Si).

18. The reflective mask blank according to claim 3, wherein the material of the absorber film comprises at least one selected from iridium (Ir) and ruthenium (Ru).

19. The reflective mask blank according to claim 3, wherein the material of the absorber film comprises platinum (Pt).

20. The reflective mask blank according to claim 3, wherein the material of the absorber film comprises gold (Au).
